(19) United States
(12) Patent Application Publication
(10) Pub. No.: US 2004/0075982 A1
(43) Pub. Date: Apr. 22, 2004

(54) Heat sink frame with improved electromagnetic interference (EMI) suppression characteristics

(76) Inventors: David K. Kim, San Jose, CA (US); William W. Ruckman, San Jose, CA (US); Wenjun Chen, Fremont, CA (US); James H. Poore, San Jose, CA (US)

Correspondence Address: Ramin Aghevli, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/277,185

(22) Filed: Oct. 21, 2002

(51) Int. Cl. G06F 1/20; H05K 7/20

(52) U.S. Cl. 361/687; 361/718

(57) ABSTRACT

Disclosed are novel methods and apparatus for provision of a heat dissipation device with improved EMI suppression characteristics. In accordance with an embodiment of the present invention, an apparatus is disclosed. The apparatus may include a printed circuit board, which forms at least one grounding pad and at least one mounting hole. The apparatus may further include an integrated circuit, a heat dissipation device mounted on the integrated circuit, and a frame mounted on the printed circuit board through the mounting hole. The frame may include at least one frame leg in electrical contact with the grounding pad. The frame may form an electromagnetic interference (EMI) shield to limit an EMI leakage generated by the integrated circuit.

### FIELD OF INVENTION

The present invention generally relates to the field of integrated circuits (ICs). More specifically, an embodiment of the present invention relates to suppressing electromagnetic interference (EMI) generated by ICs.

### BACKGROUND OF INVENTION

With the rapid development of technology, the speed of central processing units (CPUs) within computer systems has increased. However, the increased speed of CPUs increases the level of electromagnetic field interference (EMI) that is generated.

Typical computer systems include a heat spreader and a heat sink clipped over a CPU to a motherboard for thermal management. EMI noise generated by the CPU may be coupled to the heat spreader and heat sink. The heat spreader and heat sink may radiate the noise causing interference in other components within the computer system.

Current and next generation technologies require shorter rise times and faster clock rates in order to be competitive in the world market. Static-based (i.e., low frequency) methods for shielding sensitive equipment and components (such as ICs) are instructional, but lack the necessary isolation at the higher frequencies. Generally, known shielding principles are useful for low frequencies (e.g., less than 200 MHz). However, chassis resonance occurs at higher frequencies.

Moreover, cavities may be excited by electric field and magnetic field coupling on printed circuit boards (PCBs). Similarly, heat sinks and reference planes may capacitively couple to the circuits and the chassis. Also, large currents conducted in bus connectors, traces, and cables may couple magnetic fields that may, in turn, excite the chassis.

Energy coupled to the chassis results in currents conducted on the interior of the chassis surface. When these currents are forced around slots, seams, and apertures, electric fields and magnetic fields are generated in the slot. The slot may then function as a magnetic dipole antenna. This will be, especially, an effective EMI antenna at frequencies at which the slot length is a multiple of a quarter wavelength of the signal.

Some computer systems implement an EMI shield in order to ground the heat spreader and heat sink to the motherboard. Often, such EMI shields do not provide a continuous ring around the CPU, thus, not sufficiently reducing the EMI noise generated by the CPU. Moreover, the current shield designs that implement a continuous ring around the CPU require tools for removal or replacement. Requiring tools for removal or replacement precludes the easy servicing of the computer system when necessary.

### SUMMARY OF INVENTION

The present invention, which may be utilized in a general-purpose digital computer, in certain embodiments, includes novel methods and apparatus to provide a heat dissipation device with improved EMI suppression characteristics. In accordance with an embodiment of the present invention, an apparatus is disclosed. The apparatus may include a printed circuit board, which forms at least one grounding pad and at least one mounting hole. The apparatus may further include an integrated circuit, a heat dissipation device mounted on the integrated circuit, and a frame mounted on the printed circuit board through the mounting hole. The frame may include at least one frame leg in electrical contact with the grounding pad.

In another embodiment of the present invention, the frame forms an electromagnetic interference (EMI) shield to limit an EMI leakage generated by the integrated circuit.

In a further embodiment of the present invention, the heat dissipation device and/or the frame may prevent a passage of EMI through a juncture of the frame and a conductive layer of the printed circuit board.

In yet another embodiment of the present invention, the frame may further include a plurality of locking lips to slideably engage the heat dissipation device and the frame.

In a different embodiment of the present invention, a computer system is disclosed. The computer system includes: a motherboard having a plurality of grounding pads and mounting holes, the plurality of grounding pads adjoining the plurality of mounting holes; an integrated circuit; a heat dissipation device mounted on the integrated circuit; and a frame mounted on the motherboard through the plurality of mounting holes, the frame having a plurality of frame leg in electrical contact with the plurality of grounding pads.

### BRIEF DESCRIPTION OF DRAWINGS

The present invention may be better understood and its numerous objects, features, and advantages made apparent to those skilled in the art by reference to the accompanying drawings in which:

FIG. 1 illustrates an exemplary computer system 100 in which certain embodiments of the present invention may be implemented;

FIG. 2 illustrates an exemplary exploded perspective view of an IC assembly 200 in accordance with an embodiment of the present invention;

FIG. 3 illustrates an exemplary perspective view of an IC assembly 300 in accordance with an embodiment of the present invention;

FIG. 4 illustrates an exemplary side view of an IC assembly 400 in accordance with an embodiment of the present invention;

FIG. 5 illustrates an exemplary perspective view of an IC assembly 500 in accordance with an embodiment of the present invention; and

FIG. 6 illustrates an exemplary perspective view of an IC assembly 600 in accordance with an embodiment of the present invention.

The use of the same reference symbols in different drawings indicates similar or identical items.

### DETAILED DESCRIPTION

In the following description, numerous details are set forth. It will be apparent, however, to one skilled in the art that embodiments of the present invention may be practiced without these specific details. In other instances, well-known structures, devices, and techniques have not been shown in detail, in order to avoid obscuring the understanding of the description. The description is thus to be regarded as illustrative instead of limiting.

Reference in the specification to “one embodiment” or “an embodiment”is intended to indicate that a particular feature, structure, or characteristic described in connection with the embodiment is included in at least an embodiment of the invention. The appearances of the phrase “in one embodiment” in various places in the specification are not necessarily all referring to the same embodiment.

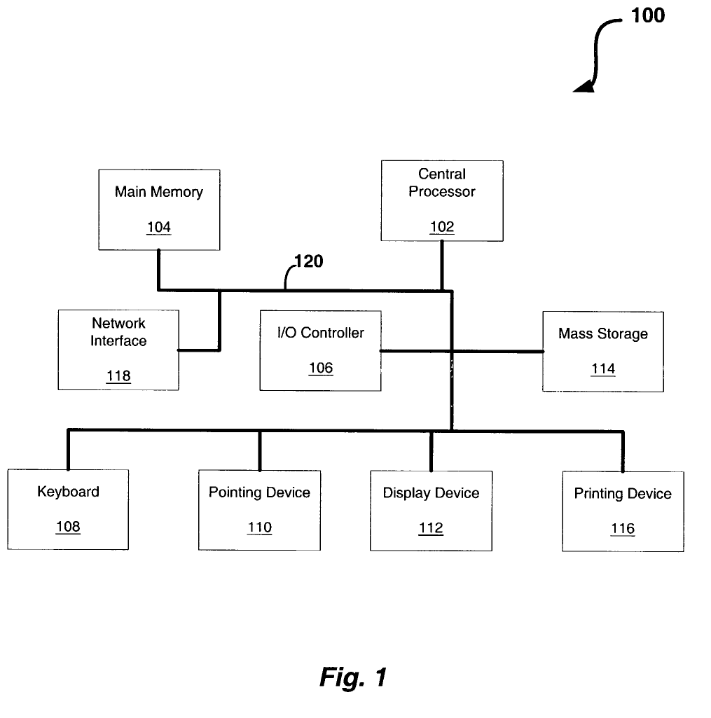

FIG. 1 illustrates an exemplary computer system 100 in which certain embodiments of the present invention may be implemented. The system 100 comprises a central processor 102 (or central processing unit (CPU)), a main memory 104, an input/output (I/O) controller 106, a keyboard 108, a pointing device 110 (e.g., mouse, track ball, pen device, or the like), a display device 112, a mass storage 114 (e.g., a nonvolatile storage such as a hard disk drive, an optical drive, and the like), and a network interface 118. Additional input/output devices, such as a printing device 116, may be included in the system 100 as desired. As illustrated, the various components of the system 100 communicate through a system bus 120 or similar architecture.

In accordance with an embodiment of the present invention, the computer system 100 includes a Sun Microsystems computer utilizing a SPARC microprocessor available from several vendors (including Sun Microsystems, Inc., of Santa Clara, Calif.). Those with ordinary skill in the art understand, however, that any type of computer system may be utilized to embody the present invention, including those made by Hewlett Packard of Palo Alto, Calif., and IBM-compatible personal computers utilizing Intel microprocessor, which are available from several vendors (including IBM of Armonk, N.Y.). Also, instead of a single processor, two or more processors (whether on a single chip or on separate chips) can be utilized to provide speedup in operations. It is further envisioned that the processor 102 may be a complex instruction set computer (CISC) microprocessor, a reduced instruction set computing (RISC) microprocessor, a very long instruction word (VLIW) microprocessor, a processor implementing a combination of instruction sets, and the like.

The network interface 118 provides communication capability with other computer systems on a same local network, on a different network connected via modems and the like to the present network, or to other computers across the Internet. In various embodiments of the present invention, the network interface 118 can be implemented utilizing technologies including, but not limited to, Ethernet, Fast Ethernet, wide-area network (WAN), leased line (such as T1, T3, optical carrier 3 (OC3), and the like), analog modem, digital subscriber line (DSL and its varieties such as high bit-rate DSL (HDSL), integrated services digital network DSL (IDSL), and the like), cellular, time division multiplexing (TDM), universal serial bus (USB and its varieties such as USB II), asynchronous transfer mode (ATM), satellite, cable modem, and/or FireWire.

Moreover, the computer system 100 may utilize operating systems such as Solaris, Windows (and its varieties such as CE, NT, 2000, XP, ME, and the like), HP-UX, IBM-AIX, PALM, UNIX, Berkeley software distribution (BSD) UNIX, Linux, Apple UNIX (AUX), Macintosh operating system (Mac OS) (including Mac OS X), and the like. Also, it is envisioned that in certain embodiments of the present invention, the computer system 100 is a general purpose computer capable of running any number of applications such as those available from companies including Oracle, Siebel, Unisys, Microsoft, and the like.

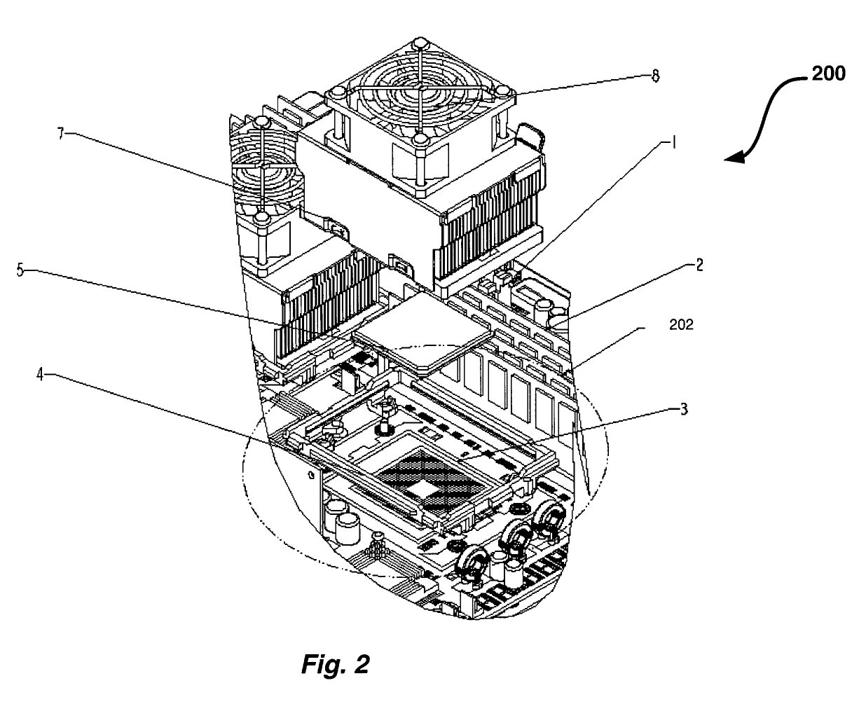

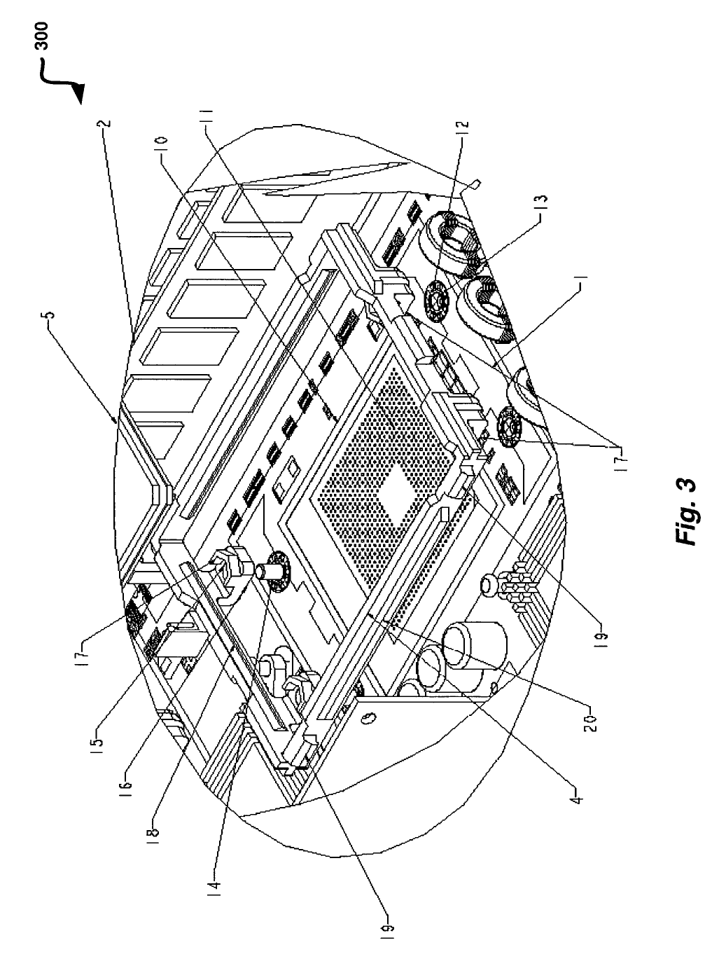

FIG. 2 illustrates an exemplary exploded perspective view of an IC assembly 200 in accordance with an embodiment of the present invention. The IC assembly 200 includes a motherboard (1), a memory bank (2), an IC socket (3), a frame (4), a CPU (5), a cooling assembly (7), and a cooling fan (8). The motherboard (1) may be a PCB in an embodiment of the present invention. The cooling fan (8) may be attached to the cooling assembly (7) by one or more, clips, screws, glue, plastic fasteners, rivets, their combinations, and the like. An embodiment of a section 202 of the IC assembly 200 is further discussed with reference to FIG. 3. The cooling assembly (7) may include a heat sink constructed with one or more material such as aluminum, steel, zinc, gold, silver, copper, alloys thereof, and the like.

The memory bank (2) may include video or other types of memory (such as discussed with respect to the main memory 104 of FIG. 1). In one embodiment of the present invention, the IC socket (3) may be a micro ball grid array (mBGA) socket. The frame (4) may have a metallic surface to be effective in conducting EMI and/or other signals. In an embodiment of the present invention, the frame (4) may be metallic or plastic with metallic coating. The metal utilized for the frame (4) (or its surface) may be aluminum, steel, zinc, gold, silver, copper, alloys thereof, and the like. The CPU (5) may be any IC such as available CPUs on the market including those discussed with respect to the central processor 102 of FIG. 1. In an embodiment of the present invention, the CPU (5) may be a metal-programmed gate array (mPGA) CPU, which may be plugged directly into the IC socket (3).

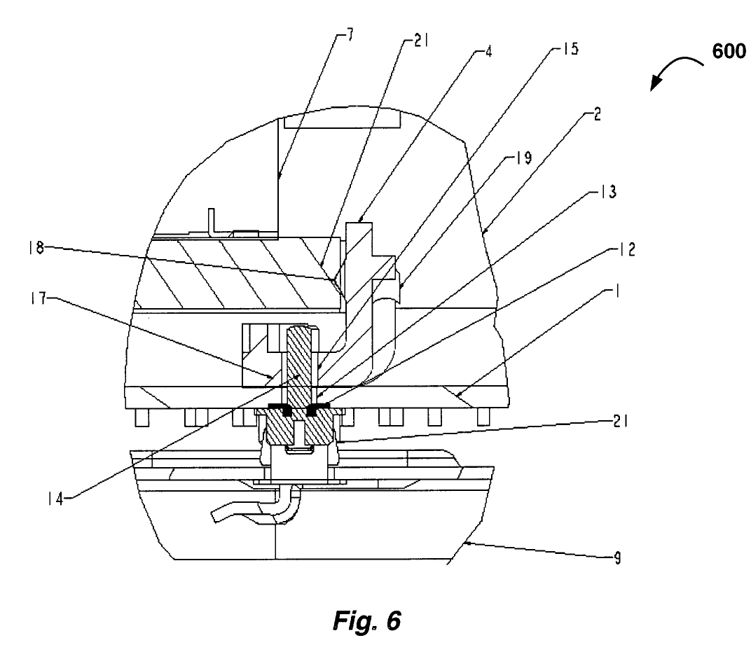

FIG. 3 illustrates an exemplary perspective view of an IC assembly 300 in accordance with an embodiment of the present invention. In one embodiment of the present invention, the IC assembly 300 may be the same or similar to the section 202 of FIG. 2. The IC assembly 300 includes the motherboard (1), the memory bank (2), the frame (4), the CPU (5), an IC socket frame (10), an IC socket grid (11) (e.g., to receive pins from the CPU (5)), one or more grounding pads (12) (e.g., see also FIG. 6), one or more mounting holes (13) (e.g., see also FIG. 6), one or more mounting pins (14), one or more pin locks (15), one or more frame feet (16), one or more frame legs (17), an EMI shield (18), and one or more locking frame lips (19 and 20).

In one embodiment, the frame (4) may include a 360-degree EMI shield (18). The frame (4) may be mounted on one or more mounting pins (14) and secured by one or more pin locks (15) to the motherboard (1) to. The mounting pins (14) and the grounding pads (12) may be metallic to conduct EMI and/or other electrical signals. The frame feet (16) may provide electrical contact with the grounding pads (12) to, for example, provide an analog and/or digital ground to prevent EMI leakage. In an embodiment of the present invention, the frame (4) may be metallic or plastic with metallic coating. The metal utilized for the frame (4) (or its surface) may be aluminum, steel, zinc, gold, silver, copper, alloys thereof, and the like.

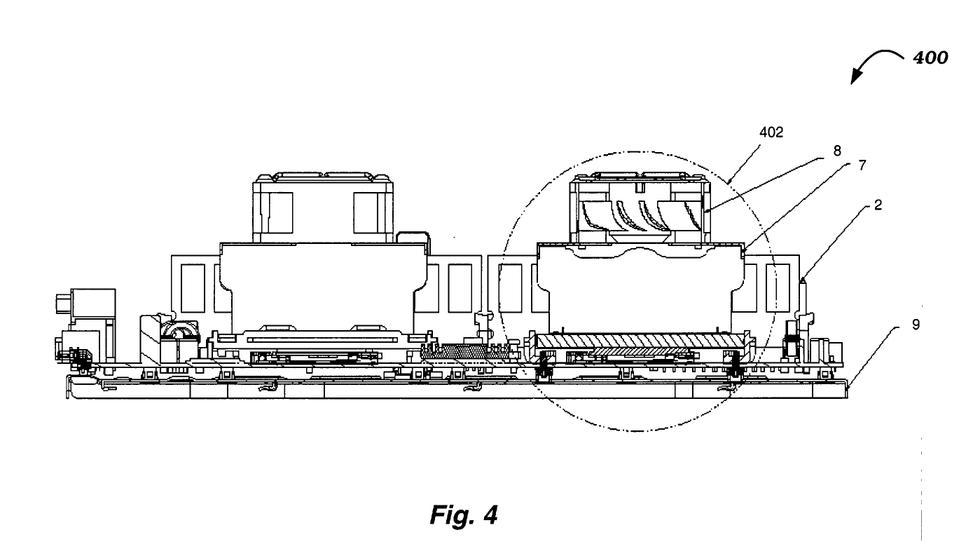

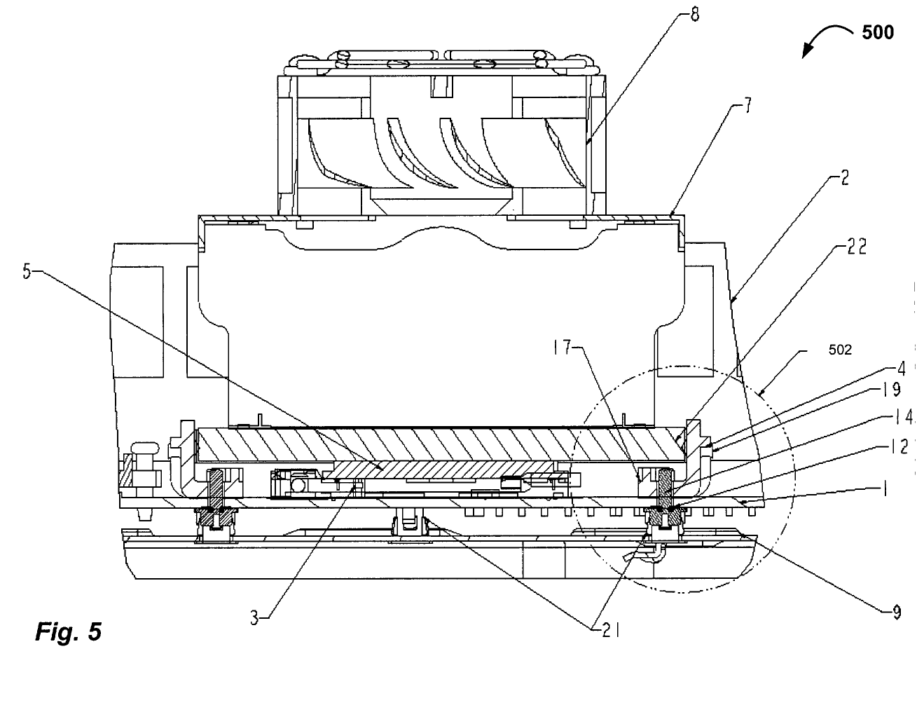

FIG. 4 illustrates an exemplary side view of an IC assembly 400 in accordance with an embodiment of the present invention. In one embodiment of the present invention, the IC assembly 400 may include the same or similar elements as the IC assembly 200 of FIG. 2 and the IC assembly 300 of FIG. 4. The IC assembly includes the memory bank (2), the cooling assembly (7), the cooling fan (8), and a base enclosure (9) (e.g., to secure the cooling fan (8) to the cooling assembly (7)). The base enclosure (9) may be constructed of various materials to, for example, limit vibration (e.g., caused by a rotating cooling fan) and/or provide structural support. Such materials may include aluminum, steel, zinc, gold, silver, plastic, copper, combinations (or alloys) thereof, and the like. An embodiment of a section 402 of the IC assembly 400 is further discussed with reference to FIG. 5. Furthermore, techniques of the present invention may be utilized for more than one CPU such as illustrated in FIG. 4.

FIG. 5 illustrates an exemplary perspective view of an IC assembly 500 in accordance with an embodiment of the present invention. In one embodiment of the present invention, the IC assembly 500 may be the same or similar to the section 402 of FIG. 4. The IC assembly 500 includes the motherboard (1), the memory bank (2), the IC socket (3), the frame (4), the CPU (5), the cooling assembly (7), the cooling fan (8), the base enclosure (9), the grounding pads (12), the mounting pins (14), the frame legs (17), the locking frame lips (19), one or more stand offs (21), and a heat sink base (22).

In one embodiment, the stand offs (21) may be constructed of conductive material (such as metallic material discussed with respect to the frame (4)) to, for example, prevent EMI to pass through to other IC components. The heat sink base (22) may provide structural rigidity and thermal benefits (such as a heat spreader) to, for example, the cooling assembly (7) and/or the CPU (5).

FIG. 6 illustrates an exemplary perspective view of an IC assembly 600 in accordance with an embodiment of the present invention. In one embodiment of the present invention, the IC assembly 600 may be the same or similar to the section 502 of FIG. 5. The IC assembly 600 includes the motherboard (1), the memory bank (2), the frame (4), the cooling assembly (7), the base enclosure (9), the grounding pads (12), the mounting holes (13), the mounting pins (14), the pin locks (15), the frame legs (17), the EMI shield (18), the locking frame lips (19), and the stand offs (21).

In accordance with an embodiment of the present invention, a heat sink assembly (including, for example, 7, 8 and 22) may be lowered onto the frame (4) and slideably pressed until the edges of the heat sink assembly contact a plurality of contact fingers formed in the EMI shield (18) (e.g., the heat sink base (22) compressing upon the domes of the EMI shield (18)). The domes of the EMI shield (18) may be integrated into the frame (4), in an embodiment of the present invention.

In a further embodiment of the present invention, a CPU assembly (4, 5, 7, 8 and 22) may contain an mBGA socket (3) reflowed onto the motherboard (1). An mPGA CPU (5) may plug directly into the socket (3). A metal and/or a plastic (with metallic coating) frame (4) having a 360-degree EMI shield (18) may then be mounted (e.g., by utilizing 13, 14, and 15) through the provided grounding pads (12) and mounting holes (13) and secured to the motherboard (1) to provide an analog and/or digital ground to limit or prevent EMI leakage from the CPU (5) (which may act as a base EMI shield in another embodiment of the present invention).

In a yet a further embodiment of the present invention, the extruded features in the frame (4) (e.g., the locking frame lips (19 and 20)) may be used as a mechanism to interlock the heat sink and the frame (4) (e.g., with a common spring clip (not shown)).

In a different embodiment of the present invention, the heat sink assembly (e.g., including 7, 8, and 22) including a common spring clip (not shown), the frame (4) on the motherboard (1), the standoffs (21), and base enclosure (9) may prevent EMI from passing through items such as the grounding pads (12), the mounting holes (13), the mounting pins (14), the pin locks (15), and the motherboard (1) to other electronic circuits (that may also be shielded). Additionally, the frame legs (17) may be positioned to prevent EMI from passing through the juncture of the EMI shield (18) with the conductive layer of the motherboard (1).

The foregoing description has been directed to specific embodiments of the present invention. It will be apparent to those with ordinary skill in the art that modifications may be made to the described embodiments of the present invention, with the attainment of all or some of the advantages. For example, the techniques of the present invention may be utilized in set-top boxes, blade computers, electronic gaming apparatus (such as those provided by Microsoft Corporation of Redmond, Washington (e.g., XBOX game machine) and Sony Corporation of Japan (e.g., PlayStation game machine)), and devices available from SONICblue Inc. of Santa Clara, Calif. (such as ReplayTV and Rio MP3 players), and the like. Therefore, it is the object of the appended claims to cover all such variations and modifications as come within the spirit and scope of the invention.

What is claimed is:

1. An integrated circuit (IC) assembly comprising:
a printed circuit board forming at least one grounding pad and at least one mounting hole;
an integrated circuit;
a heat dissipation device mounted on the integrated circuit; and
a frame mounted on the printed circuit board through the mounting hole, the frame having at least one frame leg in electrical contact with the grounding pad, wherein the frame forms an electromagnetic interference (EMI) shield to limit an EMI leakage generated by the integrated circuit.

2. The IC assembly of claim 1 wherein the integrated circuit acts as a base EMI shield.

3. The IC assembly of claim 1 wherein one or more of the heat dissipation device and the frame prevent a passage of EMI through a juncture of the frame and a conductive layer of the printed circuit board.

4. The IC assembly of claim 1 wherein the frame further includes a plurality of locking lips to slideably engage the heat dissipation device and the frame.

5. The IC assembly of claim 1 wherein the heat dissipation device and the frame are interlocked by a spring clip.

6. The IC assembly of claim 1 wherein the heat dissipation device includes one or more items selected from a group comprising a cooling assembly, a base enclosure, and a heat sink base.

7. The IC assembly of claim 6 wherein one or more of the heat dissipation device, the base enclosure, and the frame prevent a passage of EMI through a juncture of the frame and a conductive layer of the printed circuit board.

8. The IC assembly of claim 6 wherein the cooling assembly is a heat sink.

9. The IC assembly of claim 6 wherein the heat dissipation device further includes a cooling fan attached to the cooling assembly.

10. The IC assembly of claim 6 wherein the base enclosure is formed by the frame.

11. The IC assembly of claim 6 wherein the heat sink base is a heat spreader.

12. The IC assembly of claim 1 wherein the printed circuit board is a motherboard.

13. The IC assembly of claim 1 wherein the integrated circuit is a central processing unit (CPU).

14. The IC assembly of claim 1 wherein the frame prevents warpage of the printed circuit board.

15. The IC assembly of claim 1 wherein the frame physically secures at least a portion of the heat dissipation device.

16. The IC assembly of claim 1 wherein the frame electrically grounds the heat dissipation device to the printed circuit board in order to trap an EMI generated by the integrated circuit.

17. The IC assembly of claim 1 further comprising one or more mounting pins located in the mounting holes to mount the frame on the printed circuit board.

18. The IC assembly of claim 17 wherein the mounting pins align the frame and the integrated circuit, the frame being mounted on the printed circuit board.

19. The IC assembly of claim 1 wherein the frame is constructed with one or more materials selected from a group comprising aluminum, steel, zinc, gold, silver, copper, and alloys thereof.

20. The IC assembly of claim 1 wherein the frame is constructed with a plastic material having a metallic coating.

21. The IC assembly of claim 20 wherein the metallic coating is selected from a group comprising aluminum, steel, zinc, gold, silver, copper, and alloys thereof.

22. A computer system comprising:
a motherboard having a plurality of grounding pads and mounting holes, the plurality of grounding pads adjoining the plurality of mounting holes;
an integrated circuit;
a heat dissipation device mounted on the integrated circuit; and
a frame mounted on the motherboard through the plurality of mounting holes, the frame having a plurality of frame leg in electrical contact with the plurality of grounding pads.

23. The computer system of claim 22 wherein the frame forms an electromagnetic interference (EMI) shield to limit an EMI leakage generated by the integrated circuit.

24. The computer system of claim 22 wherein the frame further includes a plurality of locking lips to slideably engage the heat dissipation device and the frame.

25. The computer system of claim 22 wherein the integrated circuit is a central processing unit (CPU).

26. The computer system of claim 22 further including a plurality of integrated circuits.

27. The computer system of claim 22 wherein the frame electrically grounds the heat dissipation device to the motherboard in order to trap an EMI generated by the integrated circuit.

28. The computer system of claim 22 further comprising a plurality of mounting pins located in the plurality of mounting holes to mount the frame on the motherboard.

29. The computer system of claim 22 wherein the frame is constructed with one or more materials selected from a group comprising aluminum, steel, zinc, gold, silver, copper, and alloys thereof.

30. The computer system of claim 22 wherein the frame is constructed with a plastic material having a metallic coating.

31. The computer system of claim 30 wherein the metallic coating is selected from a group comprising aluminum, steel, zinc, gold, silver, copper, and alloys thereof.
